(19) United States
(12) Patent Application Publication
(10) Pub. No.: US 2025/0306074 A1
(43) Pub. Date: Oct. 2, 2025

(54) SYSTEM GROUND DETECTION AND AUTO-CONFIGURATION

(71) Applicant: Keithley Instruments, LLC, Solon, OH (US)

(72) Inventor: Gregory Sobolewski, Brecksville, OH (US)

(73) Assignee: Keithley Instruments, LLC, Solon, OH (US)

(21) Appl. No.: 19/086,520

(22) Filed: Mar. 21, 2025

Related U.S. Application Data
(60) Provisional application No. 63/570,157, filed on Mar. 26, 2024.

(51) Int. Cl. G01R 27/20

(52) U.S. Cl. CPC G01R 27/20

(57) ABSTRACT

The present system includes an instrument configured to couple to a device under test, where the instrument is coupled to a local ground and an earth ground, the instrument having: a signal source; a relay coupled to the local ground; a impedance between the first signal source and the relay; and one or more processors configured to execute code that causes the one or more processors to: operate the relay to either connect or disconnect the earth ground to the local ground; measure quality of a first connection to the earth ground and quality of a second connection to the local ground using the instrument, the first signal source, and the first impedance; and determine whether to continue operating the relay to either keep the earth ground connected to or disconnected from the local ground based on the quality of the first connection and the quality of the second connection.

### CROSS-REFERENCE TO RELATED APPLICATIONS

This application is a nonprovisional and claims benefit of U.S. Provisional Application No. 63/570,157, titled “SYSTEM GROUND DETECTION AND CONFIGURATION,” filed Mar. 26, 2024, the disclosure of which is incorporated herein by reference in their entirety.

### TECHNICAL FIELD

This disclosure relates to test and measurement instruments, and more particularly to detecting and configuring system ground connections.

### BACKGROUND

Low level measurements require proper shielding and grounding of devices under test (DUTs) as well as instrumentation used to make measurements. A single point connection to earth ground is often desired or even required resulting in desired setup as shown below in FIG. 1. FIG. 1 is a diagram illustrating a circuit with a DUT and several test and measurement instruments. Specifically, the circuit of FIG. 1 illustrates a single earth ground connection for the multiple instruments and the DUT. However, often when multiple instruments are connected together in a test and measurement system, multiple connections to earth ground are introduced into the test and measurement system. FIG. 2 is a circuit with multiple connections to earth when multiple instruments are used to create such a setup. Often such grounding might go unnoticed and result in incorrect measurements for extended lengths of time.

Careful examination of connected instruments coupled with manual measurements can result in proper grounding connection in such case. Such manual process is time consuming and error prone and dependent on each system implementer being careful and knowledgeable enough to consider this issue. What is needed is a way of detecting and automatically configuring system ground instead of relying on manual intervention.

### BRIEF DESCRIPTION OF THE DRAWINGS

So that the manner in which the above recited features can be understood in detail, a more particular description, briefly summarized above, may be had by reference to example implementations, some of which are illustrated in the appended drawings. It is to be noted, however, that the appended drawings illustrate only typical example implementations and are therefore not to be considered limiting of its scope.

FIG. 1 is a diagram illustrating a circuit with a DUT and several test and measurement instruments.

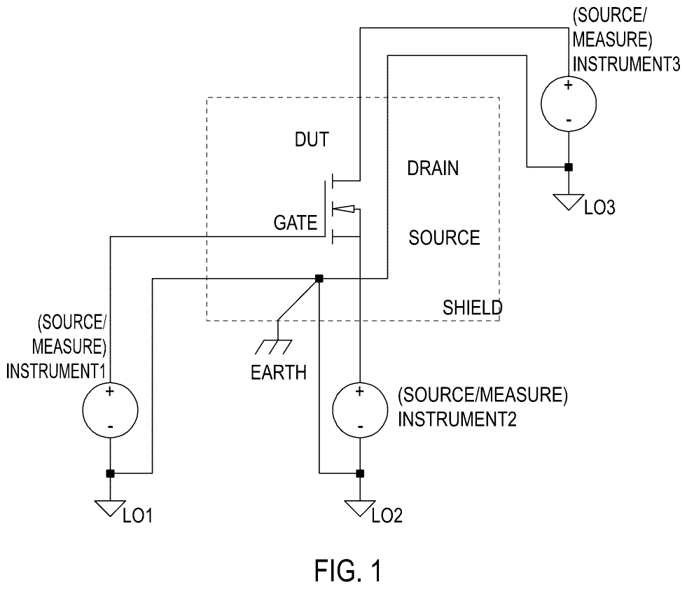

FIG. 2 is a circuit with multiple connections to earth when multiple instruments are used to create such a setup.

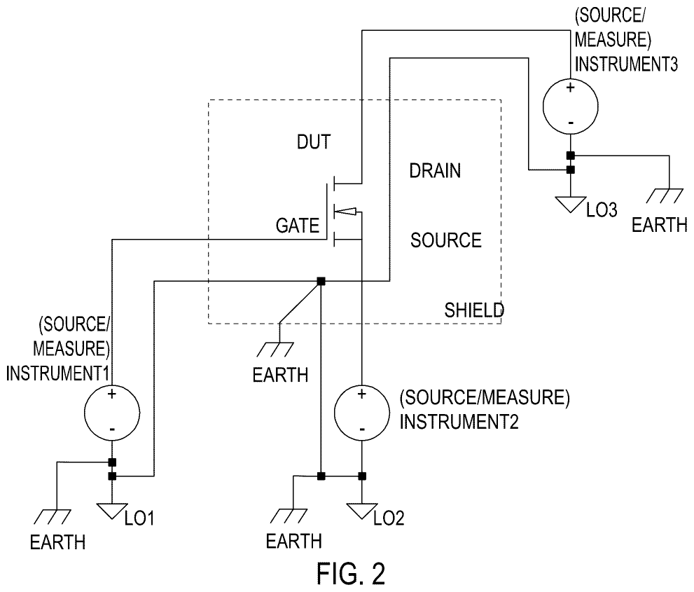

FIG. 3 illustrates a test and measurement system having multiple instruments coupled to a DUT, according to some examples.

FIG. 4 is a diagram illustrating a test and measurement system that allows for manual connection of the earth ground to local ground for a respective test and measurement instrument, according to some examples.

FIG. 5 is a diagram illustrating the circuits of FIG. 4 coupled together via a common local ground connection, according to some examples.

FIG. 6 is a diagram illustrating a flowchart of operations for a test and measurement system, according to some examples.

To facilitate understanding, identical reference numerals have been used, where possible, to designate identical elements that are common to the figures. It is contemplated that elements of one example may be beneficially incorporated in other examples.

### DETAILED DESCRIPTION

The present disclosure describes a way of detecting and automatically configuring system grounding. Examples of the present disclosure describe (1) automatically connecting and/or disconnecting the local ground of a test and measurement instrument to Earth ground; (2) measuring quality of ground connection for both direct current (DC) and alternating current (AC) voltages; (3) based on measurements above, providing guidance to the user on best connection approach or use data from that measurement to automatically determine grounding needed; and (4) monitoring system grounding as a background task and provide warning to the user when issues develop. For example, issues include cables wearing out, grounding connections coming loose, system being altered between uses, etc.

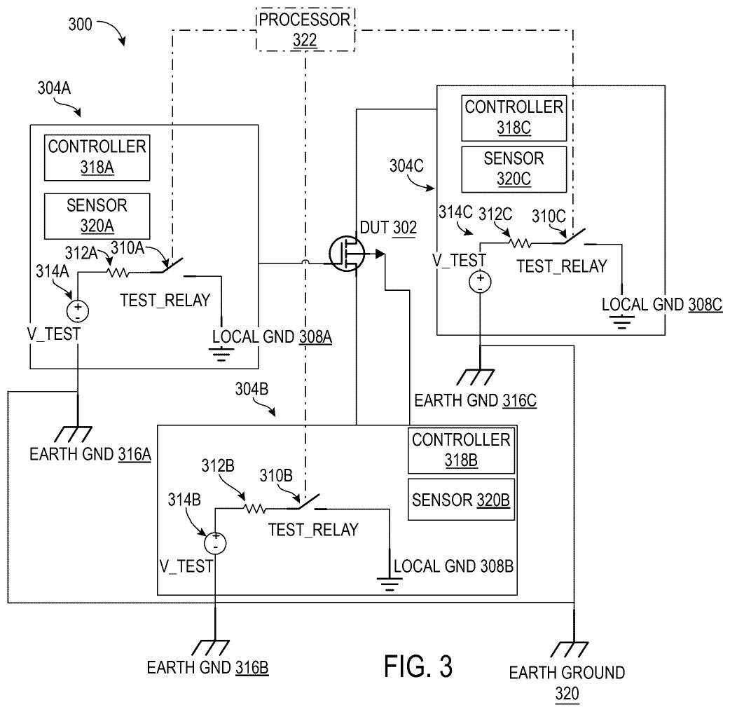

FIG. 3 illustrates a test and measurement system having multiple instruments coupled to a DUT, according to some examples. While a DUT 302 is included in FIG. 3, the test and measurement system 300 of FIG. 3 does not need to be coupled to a DUT 302 when configuring the grounding for the test and measurement system 300. Instead, the test and measurement system 300 may be couplable to the DUT 302, and for illustrative purposes, the DUT 302 is coupled to the test and measurement system 300 of FIG. 3. The test and measurement instruments 304 can be any test and measurement instrument, such as a source measure unit (SMU).

The test and measurement system 300 of FIG. 3 includes test and measurement instruments: test and measurement instrument 304A, test and measurement instrument 304B, and a test and measurement instrument 304C. While three test and measurement instruments are included in the test and measurement system 300, the test and measurement system 300 can include any number of test and measurement instruments. For example, some test and measurement systems can include one test and measurement instrument. Each test and measurement instrument of the test and measurement system 300 is couplable to any terminal of a DUT 302. In some examples, each test and measurement instrument of the test and measurement system 300 can be couplable to multiple terminals of the DUT 302 and can be couplable to any number of DUTs. Reference and description to a single test and measurement instrument 304 applies to any and each test and measurement instrument. That is, reference and description to test and measurement instrument 304 can apply to any and/or each of test and measurement instrument 304A, 304B, 304C, of the test and measurement system 300.

Each of the test and measurement instruments of the test and measurement system 300 includes a respective circuit with a local ground 308, a relay 310, an impedance 312, and a signal source 314. In some examples, each test and measurement instrument 304 is coupled to a respective, earth ground 316. Reference and description to a part of test and measurement instrument 304 applies to the respective part of any test and measurement instrument 304. That is, reference and description to the impedance 312 test and measurement instrument 304 can apply to any and/or each impedance 312 of test and measurement instruments 304A, 304B, 304C, of the test and measurement system 300. Further, reference and description to any part of test and measurement instrument 304 applies to the respective part for the respective test and measurement instrument. For example, impedance 312A is coupled to signal source 314A but is not coupled to signal source 314B as signal source 314 and impedance 312A are both a part of test and measurement instrument 304A, whereas signal source 314B is not a part of test and measurement instrument 304A.

Each test and measurement instrument 304 includes a respective local ground 308 (otherwise called instrument LO). Each test and measurement instrument 304 includes a respective relay 310, which can be any relay or switch one of ordinary skill in the art would use for connecting or disconnecting the local ground 308. The relay 310 in turn is coupled to a respective impedance 312, which can be measured via sensor 320. The impedance 312 is coupled to a respective signal source 314. The signal source 314 can be any voltage source and/or current source one of ordinary skill in the art would use for generating a voltage and/or current for the test and measurement instrument 304. The signal source 314 are coupled to earth ground 316.

As illustrated in FIG. 3, the test and measurement system 300 may have multiple earth grounds 316 for various reasons. In some examples, each test and measurement instrument 304 can introduce a new earth ground 316 despite the test and measurement system 300 having an earth ground from another component. A user of the test and measurement system 300 may not know that including a test and measurement instrument 304 into the test and measurement system 300 may introduce a new earth ground 316. As mentioned, often such grounding might go unnoticed and result in incorrect measurements for extended lengths of time. Accordingly, the present disclosure addresses examination of the connected test and measurement instruments 304 to provide proper grounding connection.

As described herein, the test and measurement system 300 involves (1) automatically connecting and/or disconnecting the local ground of a test and measurement instrument 304 to/from Earth ground; (2) measuring quality of ground connection for both DC and AC; and (3) determining whether to maintain the connection or the disconnection of the local ground 308 of the test and measurement instrument 304 to Earth ground 316. As illustrated in FIG. 3, the present disclosure involves using the test and measurement instrument 304. Specifically, for a respective test and measurement instrument, the test and measurement system 300 verifies the presence or lack of earth ground connection to the instrument local ground 308. The test and measurement instrument 304 enables a check of the ground connection using the signal source 314 coupled with the impedance 312 coupled to earth ground 316. Accordingly, when the relay 310 is operated and connects local ground 308 to earth ground 316, the test and measurement system 300, via the test and measurement instrument 304, can verify presence or lack of earth ground connection to the local ground 308 on a per test and measurement instrument basis.

Once the test and measurement system 300 determines that presence or lack of connection between local ground 308 and earth ground 316 for a respective test and measurement instrument 304, the test and measurement system 300 can determine whether to maintain the connection or disconnection between local ground 308 and earth ground 316 for the respective test and measurement instrument 304.

Each test and measurement instrument 304 includes a processor 318, which operates the relay 310 and may operate the sensor 320. The processor 318 may also be coupled to other components of the test and measurement instrument 304. One or more processors 318 may be configured to execute instructions from memory (not illustrated) and may perform any methods and/or associated steps indicated by such instructions, such as operating the relay 310; sending instructions to measure the quality of the connections to earth ground 316 and local ground 308 by measuring across the impedance 312 using the sensor 320; and determining whether to maintain the state of connection or disconnection for the relay 310. The one or more processors 318 control operation of the relays 310, the sensor 320 304, and the signal source 314. Accordingly, the processor 318 of the test and measurement system 300 facilitates the ground detection and configuration thereof for the test and measurement system 300.

In some examples, operation of the relay 310 connects the local ground 308 to the respective impedance 312 and to the respective signal source 314. The relay 310 may also disconnect the local ground 308 of the respective test and measurement instrument 304 from the respective impedance 312 and from the respective signal source 314. Similarly, operation of relays 310 can connect the local ground 308 to the earth ground 316 and to the respective signal source 314. The relay 310, may also disconnect the local ground 308 from the earth ground 316 and from the respective signal source 314. In some examples, the relay 310 can comprise any type of switch that can be controlled by the processor 322.

Upon connection or disconnection between the earth ground 316 and the local ground 308, the test and measurement system 300 measures the quality of the connection to earth ground 316 and the quality of the connection to local ground 308 per test and measurement instrument 304. For example, test and measurement instrument 304 can measure the quality of the connection between itself and earth ground 316 when the relay 310 connects the earth ground 316 to the local ground 308. The test and measurement instrument 304 can measure the quality of the connection between itself and local ground 308 when the relay 310 disconnects the earth ground 316 from the local ground 308.

Once the test and measurement system 300 measures the quality of the connections to local ground 308 and earth ground 316, the processor 318 can determine whether to keep the connection or disconnection between earth ground 316 and local ground 308 for each test and measurement instrument 304. If the processor 318 determines to not keep the connection or disconnection between earth ground 316 and local ground 308 for a test and measurement instrument 304, the processor 318 instructs the operation of the respective relay 310 to make a disconnection or connection between earth ground 316 and local ground 308 for the respective instrument 304.

As described herein, the instrument 304 can be used to analyze the presence of an earth ground connection as well as its quality. Such instrument 304 can also alert users as to presence of other earth ground connections in the test and measurement system 300. If all instruments 304 are capable of such measurement, all of them can step through the test described herein to determine optimum ground connection.

In some examples, the test and measurement instrument 304 can include current sources or voltage sources for the signal source 314 shown in FIG. 3. In some examples, the signal source 314 can produce direct current (DC) and/or alternating current (AC) voltages. In some further examples, instead of a single voltage source coupled to the respective impedance, multiple voltage sources can be coupled to the impedance 312 to provide either DC or AC voltages. In some examples, the impedance 312 can be either resistors, inductors, other electrical components, and/or any combination thereof. The instrument 304 can include a voltage limited current source, a pulse source/measure or impedance measurement, or any combination above.

In some examples, the test and measurement system includes a separate processor 322, which may operate the relay 310. The processor 322 may also be coupled to the test and measurement instruments 304 and may coordinate the operation of the relays 310 of the test and measurement instrument. One or more processors 322 may be configured to execute instructions from memory (not illustrated) and may perform any methods and/or associated steps indicated by such instructions, such as operating the relay 310; sending instructions to measure the quality of the connections to earth ground 316 and local ground 308 by measuring across the impedance 312 using the sensor 320; and determining whether to maintain the state of connection or disconnection for the relay 310. Accordingly, the processor 322 of the test and measurement system 300 facilitates the ground detection and configuration thereof for the test and measurement system 300.

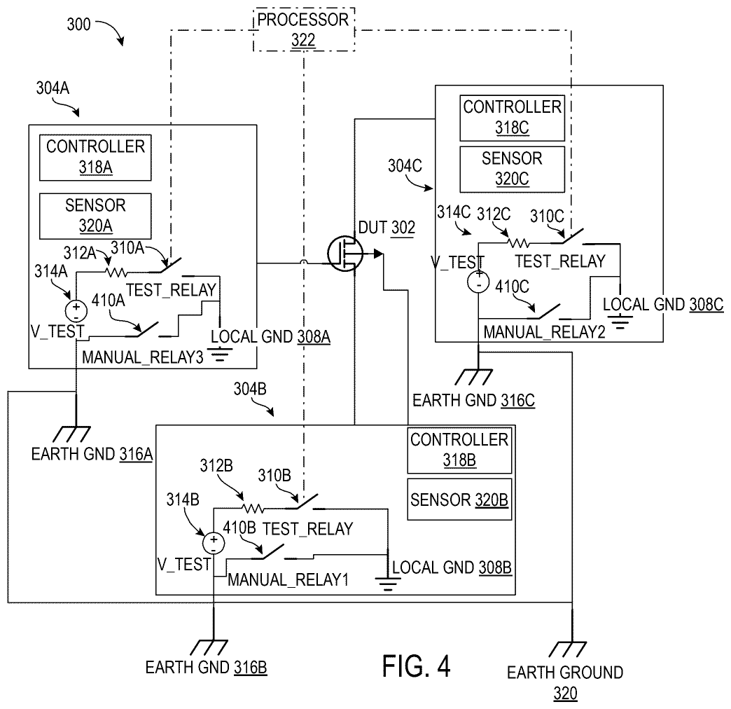

FIG. 4 is a diagram illustrating a test and measurement system that allows for manual connection of the earth ground to local ground for a respective test and measurement instrument, according to some examples. As illustrated, the test and measurement system 400 of FIG. 4 is similar to the test and measurement system 300 of FIG. 3. The test and measurement system 400 of FIG. 4 includes relays 410 between local ground 308 and earth ground 316. Each instrument 304 allows for manual connection of the earth ground 316 to local ground 308. The processor 318 and/or the processor 322 of test and measurement system 400 of FIG. 4 operates the relays 410 to connect or disconnect local ground 308 to earth ground 316, in accordance with the need to maintain connection or disconnection between local ground 308 and earth ground 316 as described herein.

In further examples, the test and measurement system described herein involves based on measurements above, providing guidance to the user on best connection approach or use data from that measurement to automatically determine grounding needed; and monitoring system grounding as a background task and provide warning to the user when issues develop. In such examples, the processor 318 and/or the processor 322 receives the information regarding the quality of connections to earth ground 316 and local ground 308 per test and measurement instrument 304, and using the information, the processor 318 and/or the processor 322 provides options to the user for the grounding configurations available. In some examples, the processor 318 and/or the processor 322 of the test and measurement system 300 can select one or more relays 310, 410 for connection and/or disconnection between local ground 308 and earth ground 316. For example, the processor 318 and/or the processor 322 can select relay 310A to allow for a connection to earth ground 316A and operate relays 310B and 310C for disconnection from earth ground 316B and 316C. The processor 318 and/or the processor 322 can configure the grounding arrangement in the test and measurement system 300 as needed or as desired by a user. In some examples, the test and measurement system 300 regularly monitors the grounding of the test and measurement system 300 as a background process. In such examples, the processor 318 and/or the processor 322 operates the relay 310 of the test and measurement instruments 304, instructs the respective test and measurement instrument 304 to measure the quality of the connections to earth ground 316 and to local ground, receives the information regarding the quality of the grounding connections, and makes determinations based on the information of the grounding quality. The processor 318 and/or the processor 322 can warn the user regarding any changes to the quality of the grounding in the test and measurement system 300 based on the background monitoring, and the user can make corresponding adjustments based on the warnings from the test and measurement system 300. In some examples, the test and measurement system 300 further includes memory (not illustrated) for the processors 318, 322, which may be implemented as processor cache, random access memory (RAM), read only memory (ROM), solid state memory, hard disk drive(s), or any other memory type. Memory (not illustrated) acts as a medium for storing data, computer program products, and other instructions. In some examples, the test and measurement system 300 includes a user interface (not illustrated), which receives user inputs that are coupled to the one or more processors 318, 322. User inputs may include a keyboard, mouse, trackball, touchscreen, and/or any other controls employable to allow a user to interact with a GUI on display (not illustrated). The display (not illustrated) may be a digital screen or any other monitor to display waveforms, measurements, and other data to a user. While the components of the test and measurement system 300 are not illustrated herein, it will be appreciated by a person of ordinary skill in the art that any of these components can be integrated and/or external to any of the test and measurement instruments 304 and can be coupled to the test and measurement instrument 304 in any conventional manner.

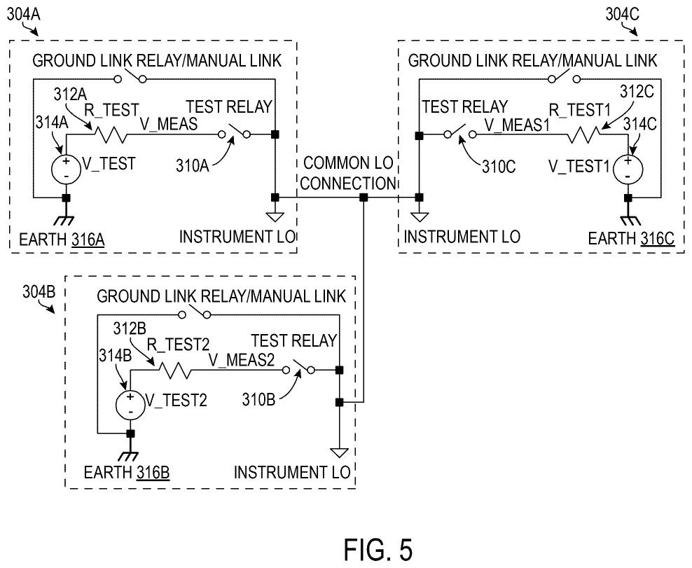

FIG. 5 is a diagram illustrating the test and measurement instruments 304 of FIG. 3 coupled together via a common local ground connection. While FIG. 5 does not show the rest of the test and measurement system of FIG. 3, description of the test and measurement system of FIG. 3 applies to the test and measurement instruments 304 of FIG. 5. In some examples, the test and measurement system of FIG. 3 can be implemented when the local grounds 308 of the test and measurement instruments 304 are coupled together.

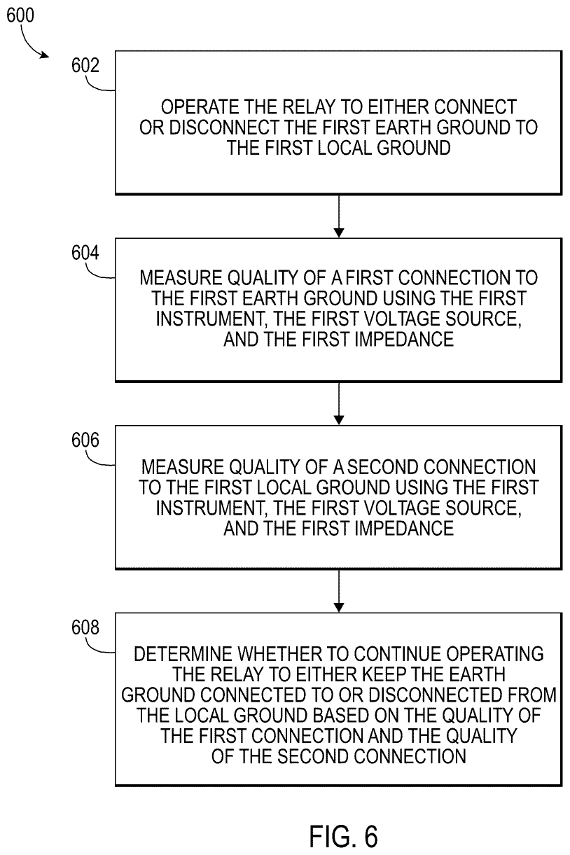

FIG. 6 is a diagram illustrating a flowchart of operations for a test and measurement system, according to some examples. Operations 600 is described with reference to the test and measurement system 300 of FIG. 3 but may also be implemented with test and measurement system 400 of FIG. 4. In some examples, the operations 600 may occur when the DUT 104 is coupled to any of the test and measurement instruments 304 of FIG. 3 or test and measurement instruments 304 of FIG. 4.

Operations 600 begins with operation 602, which involves operating a relay to either connect or disconnect a first earth ground to a first local ground. The relay can be relay 310 of FIG. 3, the first earth ground can be earth ground 316, and the first local ground can be local ground 308. In some examples, the processor (e.g., processor 318 of FIG. 3) of the test and measurement system sends signals to operate the relay. Operation of the relay can be to either connect the first earth ground to the first local ground or disconnect the first earth ground from the first local ground.

Operations 600 continues with operation 604, which involves measuring quality of a first connection to the first earth ground using the first test and measurement instrument (e.g., test and measurement instrument 304 of FIG. 3), the first signal source (e.g., signal source 314 of FIG. 3), and the first impedance (e.g., impedance 312 of FIG. 3). After operating the relay to form a connection or a disconnection between the first earth ground and the first local ground, the test and measurement system measures the quality of a first connection of the test and measurement instrument to the first earth ground. That is, the test and measurement instrument can measure the quality of the connection between itself and earth ground when the relay connects the earth ground to the local ground via a sensor (e.g., sensor 320 of FIG. 3). Measuring quality can involve measuring resistance and/or impedance between the first earth ground and the first local ground. In some examples, determining quality of the first connection involves a measurement of impedance at a predetermined frequency or through a sweep of impedance vs frequency. The quality of the connection from the test and measurement instrument to earth ground maybe inversely proportional to a measured impedance value. In some examples, the quality of the first connection requires a DC voltage source in order to measure resistance, or an AC voltage source to measure impedance. In some examples, a current source can replace the signal source, and a test and measurement instrument may still be able to determine the quality of connection based on the generated current from the current source. Upon measuring the quality of the connection between the test and measurement instrument and ground (either local ground or earth ground), the test and measurement instrument transmits the corresponding information regarding the quality of the connection to the processor.

Operations 600 continues with operation 606, which involves measuring quality of a second connection to the first local ground using the first test and measurement instrument, the first voltage source, and the first impedance. In some examples, the test and measurement instrument can measure the quality of the connection between itself and local ground when the relay disconnects the earth ground from the local ground via a sensor (e.g., sensor 320 of FIG. 3). The quality of the connection from the test and measurement instrument to local ground maybe inversely proportional to a measured impedance value. In some examples, the quality of the second connection requires a DC voltage source in order to measure resistance, or an AC voltage source to measure impedance. In some examples, a current source can replace the signal source, and a test and measurement instrument may still be able to determine the quality of connection based on the generated current from the current source. Upon measuring the quality of the connection between the test and measurement instrument and ground (either local ground or earth ground), the test and measurement instrument transmits the corresponding information regarding the quality of the connection to the processor.

Operations 600 continues with operation 608, which involves determining whether to continue operating the first relay to either keep the earth ground connected to or disconnected from the local ground based on quality of the first connection and the second connection. In some examples, determining whether to operate the first relay depends on a comparison of the quality of the first connection and the quality of the second connection. In some examples, the user is able to override the determination of whether to operate the first relay to either keep the earth ground connected to or disconnected from the local ground based on quality of the first connection and the second connection. That is, in such examples, the user is able to choose whether to operate the first relay to either keep the earth ground connected to or disconnected from the local ground. In some examples, the manual relay (e.g., relay 410 of FIG. 4) may be used when the user decides to override the determination in operation 608.

In some examples, operations 600 involves based on measurements above, providing guidance to the user on best connection approach or use data from that measurement to automatically determine grounding needed; and/or monitoring system grounding as a background task and provide warning to the user when issues develop. In such examples, the processor receives the information regarding the quality of connections to earth ground and local ground per test and measurement instrument, and using the information, the processor provides options to the user for the grounding configurations available. In some examples, the processor of the test and measurement system can select one or more relays for connection and/or disconnection between local ground and earth ground. For example, the processor can select relay to allow for a connection to earth ground and operate relays for disconnection from earth ground. The processor can configure the grounding arrangement in the test and measurement system as needed or as desired by a user. In some examples, the test and measurement system regularly monitors the grounding of the test and measurement system as a background. In such examples, the processor operates the relay of the circuits, instructs the respective test and measurement instrument to measure the quality of the connections to earth ground and to local ground, receives the information regarding the quality of the grounding connections, and makes determinations based on the information of the grounding quality. The processor can warn the user regarding any changes to the quality of the grounding in the test and measurement system based on the background monitoring, and the user can make corresponding adjustments based on the warnings from the test and measurement system.

Aspects of the disclosure may operate on a particularly created hardware, on firmware, digital signal processors, or on a specially programmed general purpose computer including a processor operating according to programmed instructions. The terms controller or processor as used herein are intended to include microprocessors, microcomputers, Application Specific Integrated Circuits (ASICs), and dedicated hardware controllers. One or more aspects of the disclosure may be embodied in computer-usable data and computer-executable instructions, such as in one or more program modules, executed by one or more computers (including monitoring modules), or other devices. Generally, program modules include routines, programs, objects, components, data structures, etc. that perform particular tasks or implement particular abstract data types when executed by a processor in a computer or other device. The computer executable instructions may be stored on a non-transitory computer readable medium such as a hard disk, optical disk, removable storage media, solid state memory, Random Access Memory (RAM), etc. As will be appreciated by one of skill in the art, the functionality of the program modules may be combined or distributed as desired in various aspects. In addition, the functionality may be embodied in whole or in part in firmware or hardware equivalents such as integrated circuits, field programmable gate arrays (FPGAs), and the like. Particular data structures may be used to more effectively implement one or more aspects of the disclosure, and such data structures are contemplated within the scope of computer executable instructions and computer-usable data described herein.

The disclosed aspects may be implemented, in some cases, in hardware, firmware, software, or any combination thereof. The disclosed aspects may also be implemented as instructions carried by or stored on one or more or non-transitory computer-readable media, which may be read and executed by one or more processors. Such instructions may be referred to as a computer program product. Computer-readable media, as discussed herein, means any media that can be accessed by a computing device. By way of example, and not limitation, computer-readable media may comprise computer storage media and communication media.

Computer storage media means any medium that can be used to store computer-readable information. By way of example, and not limitation, computer storage media may include RAM, ROM, Electrically Erasable Programmable Read-Only Memory (EEPROM), flash memory or other memory technology, Compact Disc Read Only Memory (CD-ROM), Digital Video Disc (DVD), or other optical disk storage, magnetic cassettes, magnetic tape, magnetic disk storage or other magnetic storage devices, and any other volatile or nonvolatile, removable or non-removable media implemented in any technology. Computer storage media excludes signals per se and transitory forms of signal transmission.

Communication media means any media that can be used for the communication of computer-readable information. By way of example, and not limitation, communication media may include coaxial cables, fiber-optic cables, air, or any other media suitable for the communication of electrical, optical, Radio Frequency (RF), infrared, acoustic or other types of signals.

### EXAMPLES

Illustrative examples of the disclosed technologies are provided below. An embodiment of the technologies may include one or more, and any combination of, the examples described below.

Example 1 is a test and measurement system, including: a first instrument configured to couple to a device under test (DUT), where the first instrument is coupled to a first local ground and to a first earth ground, the first instrument including: a first signal source coupled to the first earth ground; a first relay coupled to the first local ground; a first impedance coupled between the first signal source and the first relay; and one or more processors configured to execute code that causes the one or more processors to: operate the first relay to either connect or disconnect the first earth ground to the first local ground; measure quality of a first connection to the first earth ground using the first instrument, the first signal source, and the first impedance; measure quality of a second connection to the first local ground using the first instrument, the first signal source, and the first impedance; and determine whether to continue operating the first relay to either keep the first earth ground connected to or disconnected from the first local ground based on the quality of the first connection and the quality of the second connection.

Example 2 is the test and measurement system of Example 1, where the first instrument further may include: a second relay coupled between the first earth ground and the first local ground, and where the one or more processors is configured to operate the second relay to either connect or disconnect the first earth ground and the first local ground.

Example 3 is the test and measurement instrument of Example 1 or Example 2, further including a second instrument configured to be coupled to the DUT, where the second instrument is coupled to a second earth ground, where the second instrument may include: a second local ground; a second signal source coupled to the second earth ground; a second relay coupled to the second local ground; and a second impedance coupled between the second signal source and the second relay.

Example 4 is the test and measurement instrument of any one of Example 1-3, where each of the first and second instruments are coupled to a different terminal of the DUT.

Example 5 is the test and measurement system of any one of Example 1-4, where the second local ground is coupled to the first local ground.

Example 6 is the test and measurement system of any one of Example 1-5, further may include one or more system processors configured to execute code that causes the one or more system processors to: coordinate operation of the first relay and the second relay.

Example 7 is the test and measurement instrument of any one of Example 1-6, further including a user interface configure to provide a user information regarding the quality of connection of the first instrument to the first earth ground.

Example 8 is the test and measurement system of any one of Example 1-7, where the one or more processors is further configured to monitor grounding in the test and measurement system and provide information to a user when system grounding changes.

Example 9 is the test and measurement system of any one of Example 1-8, where the first impedance is a resistor.

Example 10 is the test and measurement system of any one of Example 1-9, where the first impedance is an inductor.

Example 11 is the test and measurement system of any one of Example 1-10, where the first signal source is a voltage source.

Example 12 is the test and measurement system of any one of Example 1-11, where the first instrument has a first terminal coupled to both the first earth ground and the first local ground and a second terminal configured to be coupled to the DUT.

Example 13 is a method for a test and measurement system, the method including: operating a first relay to either connect or disconnect a first earth ground to or from a first local ground, where the test and measurement system includes a first instrument having the first relay a first signal source, and a first impedance, where the first instrument is configured to be coupled to a device under test (DUT), where the first relay coupled to the first local ground, where the first earth ground is coupled to a first signal source; and where a first impedance coupled between the first signal source and the first relay; measuring quality of a first connection to earth ground using the first instrument, the first signal source, and the first impedance; measuring quality of a second connection to the first local ground using the first instrument, the first signal source, and the first impedance; and determining whether to continue operating the first relay to either keep the first earth ground connected to or disconnected from the first local ground based on the quality of the first connection and the quality of the second connection.

Example 14 is the method of Example 13, where the first instrument may include: a second relay coupled between the first earth ground and the first local ground, and where the method further may include operating the second relay to either connect or disconnect the first earth ground and the first local ground using the second relay.

Example 15 is the method of Example 13 or Example 14, where the test and measurement system may include: a second instrument configured to be coupled to the DUT, where the second instrument is coupled to a second earth ground and a second local ground, where the second instrument may include: a second signal source coupled to the second earth ground; a second relay coupled to the second local ground; and a second impedance coupled between the second signal source and the second relay.

Example 16 is the method of any one of Example 13-15, further including: coordinating operation of the first relay and the second relay.

Example 17 is the method of any one of Example 13-16, further including: monitoring grounding in the test and measurement system; and providing information to a user when system grounding changes.

Example 18 is the method of any one of Example 13-17, where the first impedance is a resistor.

Example 19 is the method of any one of Example 13-18, where the first impedance is an inductor.

Example 20 is the method of any one of Example 13-19, where the first signal source is a voltage source.

Additionally, this written description makes reference to particular features. It is to be understood that the disclosure in this specification includes all possible combinations of those particular features. Where a particular feature is disclosed in the context of a particular aspect or example, that feature can also be used, to the extent possible, in the context of other aspects and examples.

Also, when reference is made in this application to a method having two or more defined steps or operations, the defined steps or operations can be carried out in any order or simultaneously, unless the context excludes those possibilities.

All features disclosed in the specification, including the claims, abstract, and drawings, and all the steps in any method or process disclosed, may be combined in any combination, except combinations where at least some of such features and/or steps are mutually exclusive. Each feature disclosed in the specification, including the claims, abstract, and drawings, can be replaced by alternative features serving the same, equivalent, or similar purpose, unless expressly stated otherwise.

Although specific aspects of this disclosure have been illustrated and described for purposes of illustration, it will be understood that various modifications may be made without departing from the spirit and scope of the invention. Accordingly, the invention should not be limited except as by the appended claims.

1. A test and measurement system, comprising:
a first instrument configured to couple to a device under test (DUT), wherein the first instrument is coupled to a first local ground and to a first earth ground, the first instrument comprising:
a first signal source coupled to the first earth ground;
a first relay coupled to the first local ground;
a first impedance coupled between the first signal source and the first relay; and
one or more processors configured to execute code that causes the one or more processors to:
operate the first relay to either connect or disconnect the first earth ground to the first local ground;
measure quality of a first connection to the first earth ground using the first instrument, the first signal source, and the first impedance;
measure quality of a second connection to the first local ground using the first instrument, the first signal source, and the first impedance; and
determine whether to continue operating the first relay to either keep the first earth ground connected to or disconnected from the first local ground based on the quality of the first connection and the quality of the second connection.

2. The test and measurement system of claim 1, wherein the first instrument further comprises: a second relay coupled between the first earth ground and the first local ground, and wherein the one or more processors is configured to operate the second relay to either connect or disconnect the first earth ground and the first local ground.

3. The test and measurement instrument of claim 1, further comprising a second instrument configured to be coupled to the DUT, wherein the second instrument is coupled to a second earth ground, wherein the second instrument comprises:
a second local ground;
a second signal source coupled to the second earth ground;
a second relay coupled to the second local ground; and
a second impedance coupled between the second signal source and the second relay.

4. The test and measurement instrument of claim 3, wherein each of the first and second instruments are coupled to a different terminal of the DUT.

5. The test and measurement system of claim 3, wherein the second local ground is coupled to the first local ground.

6. The test and measurement system of claim 3, further comprises one or more system processors configured to execute code that causes the one or more system processors to:
coordinate operation of the first relay and the second relay.

7. The test and measurement instrument of claim 1, further comprising a user interface configure to provide a user information regarding the quality of connection of the first instrument to the first earth ground.

8. The test and measurement system of claim 1, wherein the one or more processors is further configured to monitor grounding in the test and measurement system and provide information to a user when system grounding changes.

9. The test and measurement system of claim 1, wherein the first impedance is a resistor.

10. The test and measurement system of claim 1, wherein the first impedance is an inductor.

11. The test and measurement system of claim 1, wherein the first signal source is a voltage source.

12. The test and measurement system of claim 1, wherein the first instrument has a first terminal coupled to both the first earth ground and the first local ground and a second terminal configured to be coupled to the DUT.

13. A method for a test and measurement system, the method comprising:
operating a first relay to either connect or disconnect a first earth ground to or from a first local ground, wherein the test and measurement system includes a first instrument having the first relay a first signal source, and a first impedance, wherein the first instrument is configured to be coupled to a device under test (DUT), wherein the first relay coupled to the first local ground, wherein the first earth ground is coupled to a first signal source; and wherein a first impedance coupled between the first signal source and the first relay;
measuring quality of a first connection to earth ground using the first instrument, the first signal source, and the first impedance;
measuring quality of a second connection to the first local ground using the first instrument, the first signal source, and the first impedance; and
determining whether to continue operating the first relay to either keep the first earth ground connected to or disconnected from the first local ground based on the quality of the first connection and the quality of the second connection.

14. The method of claim 13, wherein the first instrument comprises: a second relay coupled between the first earth ground and the first local ground, and wherein the method further comprises operating the second relay to either connect or disconnect the first earth ground and the first local ground using the second relay.

15. The method of claim 14, wherein the test and measurement system comprises:
a second instrument configured to be coupled to the DUT, wherein the second instrument is coupled to a second earth ground and a second local ground, wherein the second instrument comprises:
a second signal source coupled to the second earth ground;
a second relay coupled to the second local ground; and
a second impedance coupled between the second signal source and the second relay.

16. The method of claim 15, further comprising: coordinating operation of the first relay and the second relay.

17. The method of claim 13, further comprising:
monitoring grounding in the test and measurement system; and
providing information to a user when system grounding changes.

18. The method of claim 13, wherein the first impedance is a resistor.

19. The method of claim 13, wherein the first impedance is an inductor.

20. The method of claim 13, wherein the first signal source is a voltage source.
